(19) United States
(12) Patent Application Publication
(10) Pub. No.: US 2020/0194301 A1
(43) Pub. Date: Jun. 18, 2020

(54) METAL INTERCONNECTION AND FORMING METHOD THEREOF

(71) Applicant: UNITED MICROELECTRONICS CORP., Hsin-Chu City (TW)

(72) Inventors: Chih-Yu Wu, Tainan City (TW); Sheng-Yuan Hsueh, Tainan City (TW); Kuo-Hsing Lee, Hsinchu County (TW); Guan-Kai Huang, Tainan City (TW)

(21) Appl. No.: 16/218,401

(22) Filed: Dec. 12, 2018

(51) Int. Cl. H01L 21/768; H01L 23/522; H01L 23/528

(52) U.S. Cl. CPC H01L 21/7682; H01L 21/76802; H01L 23/5226; H01L 23/528; H01L 23/5222

(57) ABSTRACT

A metal interconnection includes a substrate, a first dielectric layer, metal wirings, air gaps and air gap dummies. The substrate includes an isolated area and a dense area. The first dielectric layer is disposed over the substrate. The metal wirings are embedded in the first dielectric layer, wherein the density of the metal wirings in the isolated area is less than the density of the metal wirings in the dense area. The air gaps are sandwiched by the metal wirings. The air gap dummies are disposed in the first dielectric layer without contacting the metal wirings. The present invention also provides a method of forming a metal interconnection.

### BACKGROUND OF THE INVENTION

### 1. Field of the Invention

The present invention relates generally to a metal interconnection and forming method thereof, and more specifically to a metal interconnection inserting air gap dummies and forming method thereof.

### 2. Description of the Prior Art

As the semiconductor industry introduces new generations of integrated circuits (IC's) having higher performance and greater functionality, the density of the elements that form the IC's is increased, while the dimensions and spacing between components or elements of the ICs are reduced, which causes a variety of problems. For example, for any two adjacent conductive features, when the distance between the conductive features decreases, the resulting capacitance (parasitic capacitance) increases. The increased capacitance results in an increase of power consumption and an increase in the resistive-capacitive (RC) time constant, i.e., an increase of signal delays. The capacitance between two adjacent conductive features (e.g., metal wirings) is a function of the dielectric constant (k value) of an insulating material filled in the space between the conductive features (also, a function of a distance between the conductive features and a size of the side surfaces of the conductive features). Therefore, the continual improvement in semiconductor IC performance and functionality is dependent upon developing insulating (dielectric) materials with low k values. Since the substance with the lowest dielectric constant is air (k=1.0), air-gaps are formed to further reduce the effective k value of metal wiring layers.

### SUMMARY OF THE INVENTION

The present invention provides a metal interconnection and forming method thereof, which inserts air gap dummies to balance the density of air gaps and metal wirings in an isolated area and the density of air gaps and metal wirings in a dense area, thereby improving the structural uniformity.

The present invention provides a metal interconnection including a substrate, a first dielectric layer, metal wirings, air gaps and air gap dummies. The substrate includes an isolated area and a dense area. The first dielectric layer is disposed over the substrate. The metal wirings are embedded in the first dielectric layer, wherein the density of the metal wirings in the isolated area is less than the density of the metal wirings in the dense area. The air gaps are sandwiched by the metal wirings. The air gap dummies are disposed in the first dielectric layer without contacting the metal wirings.

The present invention provides a method of forming a metal interconnection including the following steps. A first dielectric layer is formed over a substrate, wherein the substrate includes an isolated area and a dense area. Metal wirings are embedded in the first dielectric layer, wherein the density of the metal wirings in the isolated area is less than the density of the metal wirings in the dense area. The density of the metal wirings and air gaps sandwiched by the metal wirings would be formed are detected. While the density of the air gaps and the metal wirings in the isolated area is less than a predetermined density, air gap dummies are formed in the first dielectric layer without contacting the metal wirings in the isolated area to balance the density of the air gaps and the metal wirings in the isolated area and the density of the air gaps and the metal wirings in the dense area.

According to the above, the present invention provides a metal interconnection and forming method thereof, which inserts air gap dummies to balance the density of air gaps and metal wirings in an isolated area and the density of air gaps and metal wirings in a dense area, thereby improving the structural uniformity. That is, the density of the air gaps, the air gap dummies and the metal wirings in the isolated area can approach the density of the air gaps and the metal wirings in the dense area, or/and the local density of the air gaps, and the air gap dummies and the metal wirings around the air gaps in the isolated area can approach the density of the air gaps and the metal wirings in the dense area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts top views of a metal interconnection according to an embodiment of the present invention.

FIG. 2 schematically depicts a top view and cross-sectional views of the metal interconnection of FIG. 1 inserting air gap dummies in an isolated area according to an embodiment of the present invention.

FIG. 3 schematically depicts cross-sectional views of a metal interconnection according to an embodiment of the present invention.

FIG. 4 schematically depicts a flow chart of a method of forming a metal interconnection according to an embodiment of the present invention.

FIG. 5 schematically depicts cross-sectional views of a method of forming a metal interconnection according to an embodiment of the present invention.

### DETAILED DESCRIPTION

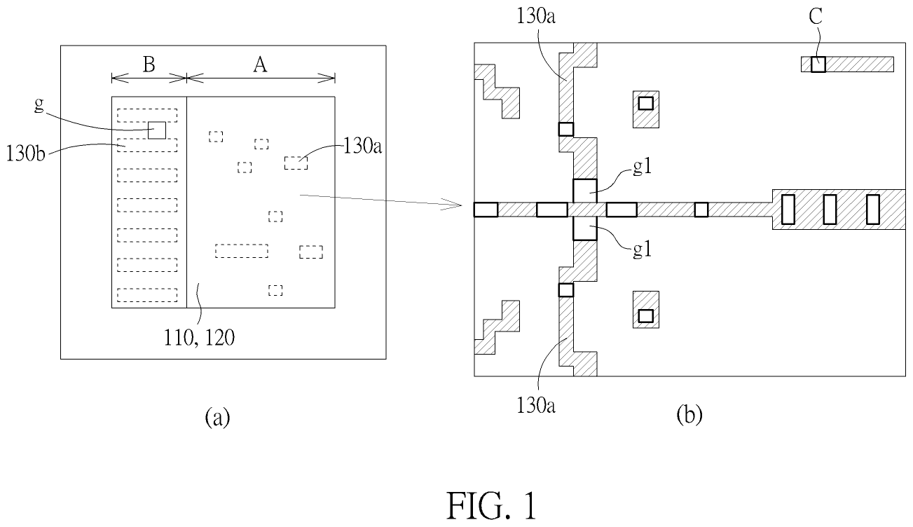

FIG. 1 schematically depicts top views of a metal interconnection according to an embodiment of the present invention. FIG. 1(a) depicts a metal interconnection of an isolated area and a dense area, and FIG. 1(b) depicts the metal interconnection of the isolated area. As shown in FIG. 1(a), a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate, a silicon-on-insulator (SOI) substrate or a substrate containing epitaxial layers. The substrate 110 may include an isolated area A and a dense area B. A first dielectric layer 120 is disposed over the substrate 110. Metal wirings 130a/130b are embedded in the first dielectric layer 120, wherein the density of the metal wirings 130a in the isolated area A is less than the density of the metal wirings 130b in the dense area B. As shown in FIG. 1(b), the metal wirings 130a are in the isolated area A, contacts C may connect components to the metal wirings 130a, and air gaps g1 are sandwiched by the metal wirings 130a. Due to the density of the metal wirings 130a in the isolated area A being less than the density of the metal wirings 130b in the dense area B, the shapes and the depths of the air gaps g1 formed between the metal wirings 130a in the isolated area A are different from the shapes and the depths of air gaps g formed between the metal wirings 130b in the dense area B.

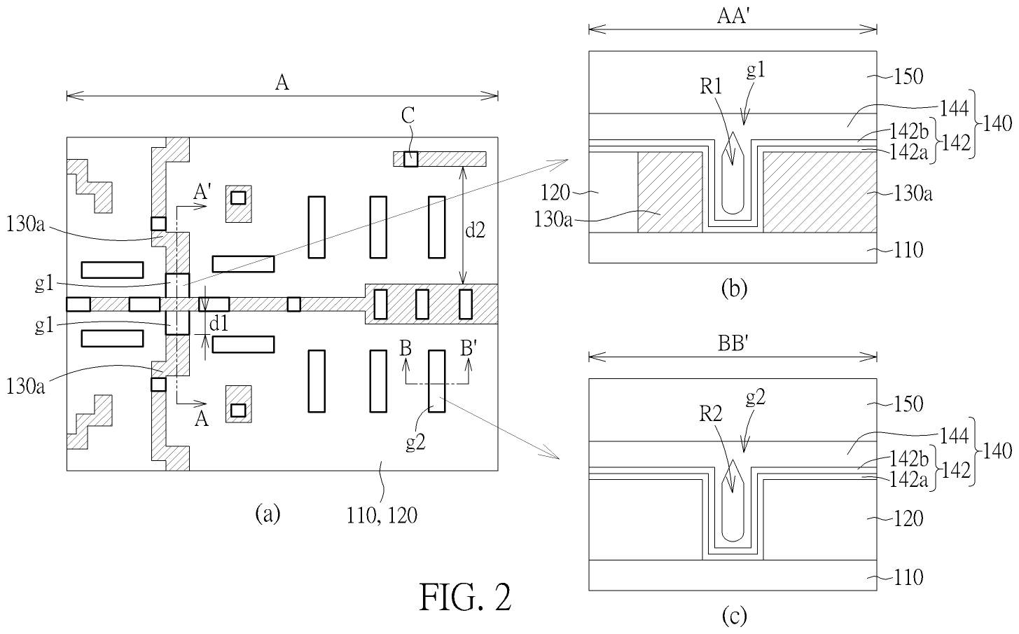

Thus, the present invention inserts air gap dummies in the isolated area A to balance the density of the air gaps g1 and the metal wirings 130a in the isolated area A and the density of the air gaps g and the metal wirings 130b in the dense area B. FIG. 2 schematically depicts a top view and cross-sectional views of the metal interconnection of FIG. 1 inserting air gap dummies in an isolated area according to an embodiment of the present invention. As shown in FIG. 2, air gap dummies g2 are disposed in the first dielectric layer 120. FIG. 2(a) depicts a layout of the air gaps g1, the air gap dummies g2, and the metal wirings 130a in the isolated area A, FIG. 2(b) depicts a cross-sectional view of each of the air gaps g1 along line AA′, and FIG. 2(c) depicts a cross-sectional view of each of the air gap dummies g2 along line BB′. Please refer to FIGS. 1-2, the air gap dummies g2 are disposed in the first dielectric layer 120 without contacting the metal wirings 130a. The density of the air gaps g1, the air gap dummies g2 and the metal wirings 130a in the isolated area A approaches the density of the air gaps g and the metal wirings 130b in the dense area B (as shown in FIG. 1). Hence, the shapes and the depths of the air gaps g1 formed between the metal wirings 130a in the isolated area A can be similar to the shapes and the depths of air gaps g formed between the metal wirings 130b in the dense area B in FIG. 1. Thus, this improves the structural uniformity and the device performance.

In this embodiment, the air gaps gl/g are disposed in the isolated area A and the dense area B, while the air gap dummies g2 are only disposed in the isolated area A, to increase the density of the air gaps g1, the air gap dummies g2 and the metal wirings 130a in the isolated area A. In another embodiment, the air gap dummies g2 may be disposed in relative isolated areas of the dense area B, depending upon practical requirements. Thus, the density of the air gaps g1, the air gap dummies g2 and the metal wirings 130a in the isolated area A or the dense area B can be adjusted.

In this case, the air gap dummies g2 are distributed around the air gaps g1 in the isolated area A, so that the local density of the air gaps g1, and the air gap dummies g2 and the metal wirings 130a around the air gaps g1 in the isolated area A can approach the density of the air gaps g and the metal wirings 130b in the dense area B. Thus, the local density of the air gaps g1, the air gap dummies g2 and the metal wirings 130a in some specific areas can be adjusted.

Preferably, the air gap dummies g2 are air gap dummy bars, and the air gap dummy bars may have common sizes such that each of the air gap dummy bars may having a width of 64 nm and a length of 128 nm, but it is not limited thereto. The air gaps g1 can only be formed between two of the metal wirings 130a as the distance between the two metal wirings 130a is less than a specific distance such as 80 nm. Therefore, as space between two of the metal wirings 130a has a distance larger than the specific distance, at least one of the air gap dummies g2 is preferably formed in the space. A distance d1 between the metal wirings 130a at opposite two sides of each of the air gaps g1 is less than a distance d2 between the metal wirings 130a at opposite two sides of each of the air gap dummies g2. In a preferred embodiment, the distance d2 between the metal wirings 130a at the opposite two sides of each of the air gap dummies g2 is larger than 80 nm, but it is not limited thereto.

Please refer to FIG. 2(b) and FIG. 2(c), each of the air gaps g1 and the air gap dummies g2 are surrounded by a U-shaped layer 140. Preferably, the air gaps g1 and the air gap dummies g2 can be formed simultaneously by common layers. Preferably, the U-shaped layer 140 may include a U-shaped nitrogen-doped silicon carbide (NDC) layer 142 and a U-shaped tetraethoxysilane (TEOS) layer 144 stacked from bottom to top; still preferably, the nitrogen-doped silicon carbide (NDC) layer 142 may include a lower nitrogen-doped silicon carbide (NDC) layer 142a and an upper nitrogen-doped silicon carbide (NDC) layer 142b stacked from bottom to top. In this case, the U-shaped layer 140 can serve as a liner, and the U-shaped layer 140 seals the openings of recesses R1/R2, therefore the air gaps g1 and the air gap dummies g2 being formed, but it is not limited thereto. More precisely, the U-shaped tetraethoxysilane (TEOS) layer 144 seals the openings of the recesses R1/R2, therefore the air gaps g1 and the air gap dummies g2 being formed in this case. In another case, the nitrogen-doped silicon carbide (NDC) layer 142 may seal the openings of the recesses R1/R2, depending upon requirements. Then, a second dielectric layer 150 is formed over the first dielectric layer 120 and the U-shaped layer 140.

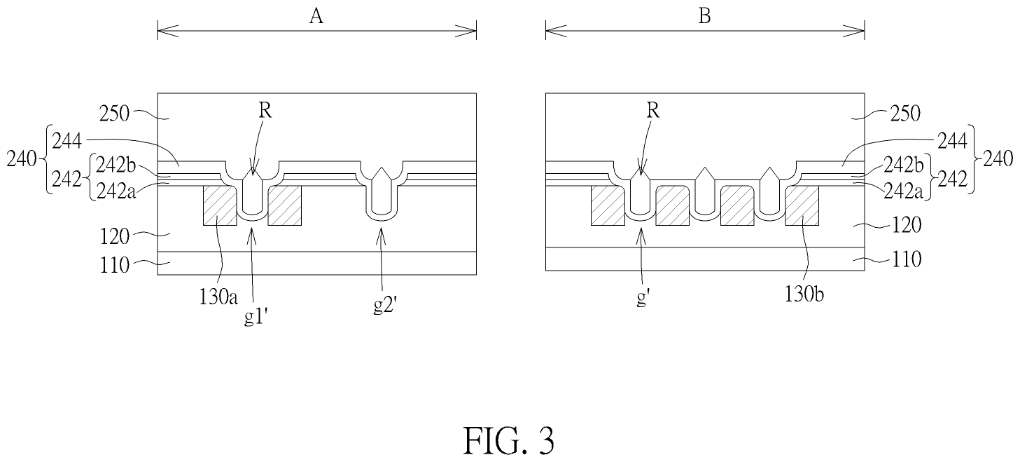

In another embodiment, the recesses R1/R2 may be sealed by the second dielectric layer 150 instead. FIG. 3 schematically depicts cross-sectional views of a metal interconnection according to an embodiment of the present invention. The left diagram of FIG. 3 depicts a part of the isolated area A and the right diagram of FIG. 3 depicts a part of the dense area B. Since the density of the metal wirings 130a and an air gap g1′ in the isolated area A is less than the density of the metal wirings 130b and air gaps g′ in the dense area B, an air gap dummy g2′ is inserted in the isolated area A. In this case, each of the air gaps g′/g1′ and the air gap dummy g2′ are surrounded by a U-shaped layer 240. In this case, the air gaps g′/g1′ and the air gap dummy g2′ can be formed simultaneously by common layers. Preferably, the U-shaped layer 240 may include a U-shaped nitrogen-doped silicon carbide (NDC) layer 242 and a U-shaped tetraethoxysilane (TEOS) layer 244 stacked from bottom to top; still preferably, the nitrogen-doped silicon carbide (NDC) layer 242 may include a lower nitrogen-doped silicon carbide (NDC) layer 242a and an upper nitrogen-doped silicon carbide (NDC) layer 242b stacked from bottom to top. The U-shaped layer 240 can serve as a liner, and a second dielectric layer 250 is formed over the first dielectric layer 120 and the U-shaped layer 240. In this case, the second dielectric layer 250 seals the openings of recesses R to form the air gaps g′/g1′ and the air gap dummy g2′.

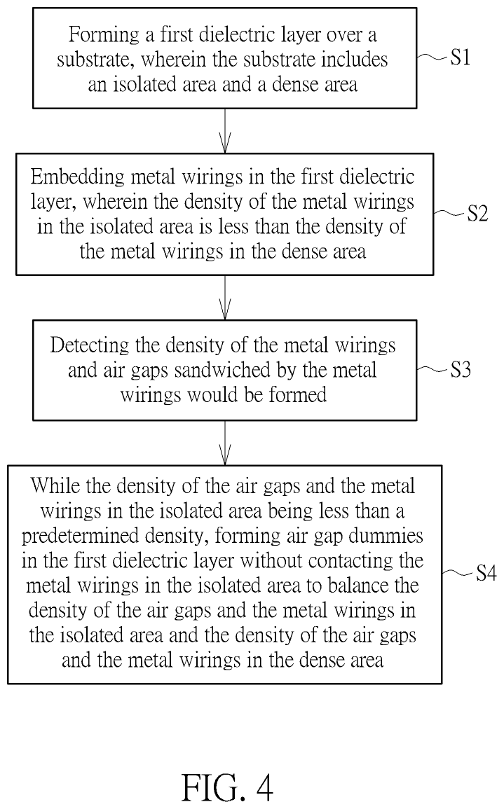

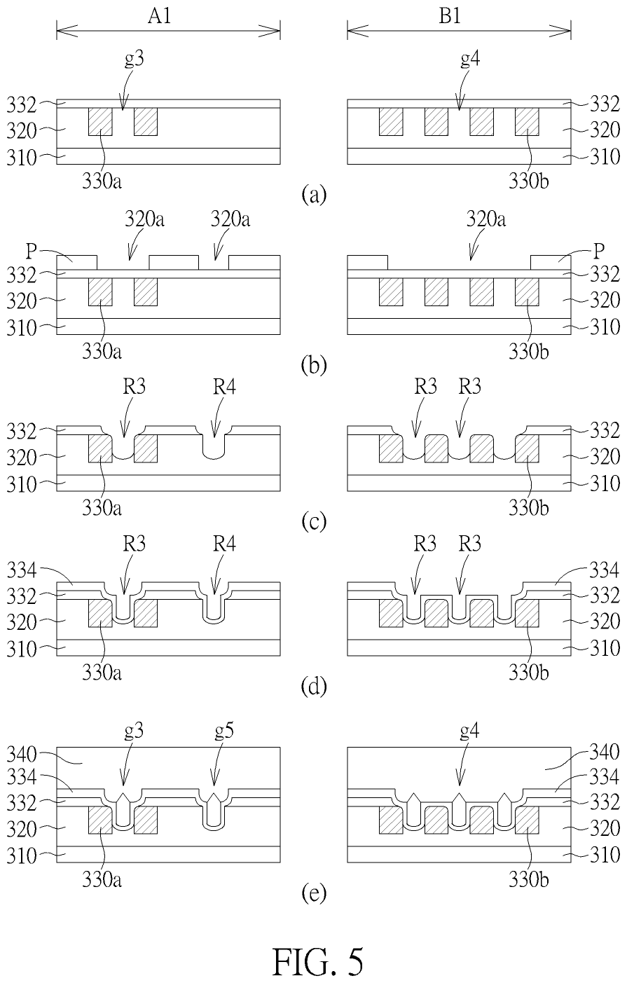

FIG. 4 schematically depicts a flow chart of a method of forming a metal interconnection according to an embodiment of the present invention. FIG. 5 schematically depicts cross-sectional views of a method of forming a metal interconnection according to an embodiment of the present invention, wherein FIG. 5 only depicts a part of an isolated area and a part of a dense area for clarifying. FIG. 4 and FIG. 5 are illustrated below. According to a step S1 of FIG. 4—forming a first dielectric layer over a substrate, wherein the substrate includes an isolated area and a dense area, a first dielectric layer 320 is formed over a substrate 310, wherein the substrate 310 includes an isolated area A1 and a dense area B1, as shown in FIG. 5(a). According to a step S2 of FIG. 4—embedding metal wirings in the first dielectric layer, wherein the density of the metal wirings in the isolated area is less than the density of the metal wirings in the dense area, metal wirings 330a/330b are embedded into the first dielectric layer 320, as shown in FIG. 5(a). The metal wirings 330a are embedded in the isolated area A1 while the metal wirings 330b are embedded in the dense area B1, wherein the density of the metal wirings 330a in the isolated area A1 is less than the density of the metal wirings 330b in the dense area B1. Then, a liner 332 may blanketly cover the metal wirings 330a/330b and the first dielectric layer 320. The liner 332 may be a nitrogen-doped silicon carbide (NDC) layer, but it is not limited thereto.

According to a step S3 of FIG. 4—detecting the density of the metal wirings and air gaps sandwiched by the metal wirings would be formed, the metal wirings 330a/330b and air gaps g3/g4 would be formed between the metal wirings 330a/330b in later process are detected in this step. As the density of the air gaps g3 and the metal wirings 330a in the isolated area A1 is less than a predetermined density, air gap dummies would be inserted in the first dielectric layer 320. In a preferred embodiment, the predetermined density is the density of the air gaps g4 and the metal wirings 130b in the dense area B1, so that the density of the air gaps g3, the metal wirings 330a and the air gap dummies can approach the density of the air gaps g4 and the metal wirings 130b in the dense area B1. As the density of the air gaps g3 and the metal wirings 330a in the isolated area A1 is larger than the predetermined density, the air gap dummies are not inserted.

According to a step S4 of FIG. 4—while the density of the air gaps and the metal wirings in the isolated area being less than a predetermined density, forming air gap dummies in the first dielectric layer without contacting the metal wirings in the isolated area to balance the density of the air gaps and the metal wirings in the isolated area and the density of the air gaps and the metal wirings in the dense area, air gap dummies g5 are formed in the first dielectric layer 320, as shown in FIG. 5(b)-FIG. 5(e). As shown in FIG. 5(b), a patterned photoresist P is formed to expose a part 320a of the first dielectric layer 320. As shown in FIG. 5(c), the part 320a of the first dielectric layer 320 is etched to form recesses R3/R4 in the first dielectric layer 320. Then, the patterned photoresist P is removed. As shown in FIG. 5(d), a liner 334 conformally covers the recesses R3/R4. In this case, the liner 334 may be a nitrogen-doped silicon carbide (NDC) layer and a tetraethoxysilane (TEOS) layer stacked from bottom to top, but it is not limited thereto. As shown in FIG. 5(e), a second dielectric layer 340 is formed over the first dielectric layer 320, and therefore seals the openings of the recesses R3/R34 to form the air gap g3 and an air gap dummy g5 in the isolated area A1, and the air gaps g4 in the dense area B1. Therefore, the density of the air gap g3, the air gap dummy g5 and the metal wirings 330a in the isolated area A1 approaches the density of the air gaps g4 and the metal wirings 330b in the dense area B1. Hence, the structural uniformity and the device performance can be improved.

In this embodiment, the air gaps g3/g4 and the air gap dummy g5 are formed at the same time, but the air gaps g3/g4 and the air gap dummy g5 may be formed in different steps. For example, the air gaps g3/g4 may be formed after the metal wirings 330a/330b are formed, and then the density of the metal wirings 330a/330b and the air gaps g3/g4 are detected (the step S3 of FIG. 4 is processed after the air gaps g3/g4 are formed). Therefore, the gap dummy g5 may be formed while the step S4 of FIG. 4—while the density of the air gaps and the metal wirings in the isolated area being less than a predetermined density, forming air gap dummies in the first dielectric layer without contacting the metal wirings in the isolated area to balance the density of the air gaps and the metal wirings in the isolated area and the density of the air gaps and the metal wirings in the dense area, is carried out, but it is not limited thereto.

To summarize, the present invention provides a metal interconnection and forming method thereof, which inserts air gap dummies to balance the density of air gaps and metal wirings in an isolated area and the density of air gaps and metal wirings in a dense area. In an embodiment of a method of forming a metal interconnection, a first dielectric layer is formed over a substrate including an isolated area and a dense area; metal wirings are embedded in the first dielectric layer, wherein the density of the metal wirings in the isolated area is less than the density of the metal wirings in the dense area; the density of the metal wirings and air gaps sandwiched by the metal wirings would be formed is detected; while the density of the air gaps and the metal wirings in the isolated area being less than a predetermined density, air gap dummies are formed in the first dielectric layer without contacting the metal wirings in the isolated area to balance the density of the air gaps and the metal wirings in the isolated area and the density of the air gaps and the metal wirings in the dense area. Hence, this improves the structural uniformity. In a preferred case, the air gaps and the air gap dummies are formed simultaneously to simplify process steps and save process costs.

By applying the present invention, a metal interconnection can be obtained. The metal interconnection may include: a first dielectric layer disposed over a substrate including an isolated area and a dense area; metal wirings embedded in the first dielectric layer, wherein the density of the metal wirings in the isolated area is less than the density of the metal wirings in the dense area; air gaps sandwiched by the metal wirings; air gap dummies disposed in the first dielectric layer without contacting the metal wirings. Thus, the density of the air gaps, the air gap dummies and the metal wirings in the isolated area can approach the density of the air gaps and the metal wirings in the dense area, or/and the local density of the air gaps, and the air gap dummies and the metal wirings around the air gaps in the isolated area can approach the density of the air gaps and the metal wirings in the dense area.

Those skilled in the art will readily observe that numerous modifications and alterations of the device and method may be made while retaining the teachings of the invention. Accordingly, the above disclosure should be construed as limited only by the metes and bounds of the appended claims.

1. A metal interconnection, comprising:
a substrate comprising an isolated area and a dense area;
a first dielectric layer disposed over the substrate;
metal wirings embedded in the first dielectric layer, wherein a density of the metal wirings in the isolated area is less than a density of the metal wirings in the dense area;
air gaps sandwiched by the metal wirings, wherein the air gaps are disposed in the isolated area and the dense area; and
air gap dummies disposed in the first dielectric layer without contacting the metal wirings.

2. The metal interconnection according to claim 1,
wherein the air gap dummies disposed in the first dielectric layer balance a density of the air gaps and the metal wirings in the isolated area and a density of the air gaps and the metal wirings in the dense area.

3. The metal interconnection according to claim 2, wherein the air gap dummies are only disposed in the isolated area.

4. The metal interconnection according to claim 3, wherein the air gap dummies are disposed in the first dielectric layer of the isolated area, so that the density of the air gaps, the air gap dummies and the metal wirings in the isolated area approaches the density of the air gaps and the metal wirings in the dense area.

5. The metal interconnection according to claim 3, wherein the air gap dummies are distributed around the air gaps in the isolated area, so that the local density of the air gaps, and the air gap dummies and the metal wirings around the air gaps in the isolated area approach the density of the air gaps and the metal wirings in the dense area.

6. The metal interconnection according to claim 1, wherein the air gap dummies comprise air gap dummy bars.

7. The metal interconnection according to claim 1, wherein a distance between the metal wirings at opposite two sides of each of the air gaps is less than a distance between the metal wirings at opposite two sides of each of the air gap dummies.

8. The metal interconnection according to claim 7, wherein the distance between the metal wirings at the opposite two sides of each of the air gap dummies is larger than 80 nm.

9. The metal interconnection according to claim 1, wherein each of the air gaps and the air gap dummies are surrounded by a U-shaped layer.

10. The metal interconnection according to claim 9, wherein the U-shaped layer comprises a U-shaped nitrogen-doped silicon carbide (NDC) layer and a U-shaped tetraethoxysilane (TEOS) layer stacked from bottom to top.

11. A method of forming a metal interconnection, comprising:
forming a first dielectric layer over a substrate, wherein the substrate comprises an isolated area and a dense area;
embedding metal wirings in the first dielectric layer, wherein the density of the metal wirings in the isolated area is less than the density of the metal wirings in the dense area;
detecting the density of the metal wirings and air gaps sandwiched by the metal wirings would be formed;
while the density of the air gaps and the metal wirings in the isolated area being less than a predetermined density, forming air gap dummies in the first dielectric layer without contacting the metal wirings in the isolated area to balance the density of the air gaps and the metal wirings in the isolated area and the density of the air gaps and the metal wirings in the dense area.

12. The method of forming a metal interconnection according to claim 11, wherein the predetermined density is the density of the air gaps and the metal wirings in the dense area.

13. The method of forming a metal interconnection according to claim 11, wherein the air gap dummies are disposed in the first dielectric layer of the isolated area, so that the density of the air gaps, the air gap dummies and the metal wirings in the isolated area approaches the density of the air gaps and the metal wirings in the dense area.

14. The method of forming a metal interconnection according to claim 11, wherein the air gap dummies are distributed around the air gaps in the isolated area, so that the local density of the air gaps, and the air gap dummies and the metal wirings around the air gaps in the isolated area approach the density of the air gaps and the metal wirings in the dense area.

15. The method of forming a metal interconnection according to claim 11, wherein a distance between the metal wirings at opposite two sides of each of the air gaps is less than a distance between the metal wirings at opposite two sides of each of the air gap dummies.

16. The method of forming a metal interconnection according to claim 11, wherein the steps of forming the air gap dummies comprise:
forming a patterned photoresist to expose a part of the first dielectric layer;
etching the part to form recesses in the first dielectric layer; and
forming a liner conformally covering the recesses.

17. The method of forming a metal interconnection according to claim 16, wherein the liner seals the openings of the recesses, therefore the air gap dummies being formed.

18. The method of forming a metal interconnection according to claim 16, wherein the steps of forming the liner conformally covering the recesses comprise:
sequentially covering a nitrogen-doped silicon carbide (NDC) layer and a tetraethoxysilane (TEOS) layer on the recesses.

19. The method of forming a metal interconnection according to claim 18, wherein the nitrogen-doped silicon carbide (NDC) layer comprises a lower nitrogen-doped silicon carbide (NDC) layer and an upper nitrogen-doped silicon carbide (NDC) layer stacked from bottom to top.

20. The method of forming a metal interconnection according to claim 16, further comprising:
forming a second dielectric layer over the first dielectric layer, and therefore seals the openings of the recesses to form the air gap dummies.
